(19) United States
(12) Patent Application Publication
(10) Pub. No.: US 2026/0101442 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventors: Bong Wee YU, Suwon-si (KR); Kyung Soo Lee, Suwon-si (KR); Jun Ho HUH, Suwon-si (KR)

(73) Assignee: SAMSUNG ELECTRONICS CO., LTD., Suwon-si (KR)

(21) Appl. No.: 19/173,232

(22) Filed: Apr. 8, 2025

(30) Foreign Application Priority Data
Aug. 30, 2024 (KR) 10-2024-0117837

(51) Int. Cl. H01L 23/00; H01L 23/538; H01L 23/64; H01L 25/16; H05K 1/18; H10B 80/00; H10D 80/30

(52) U.S. Cl. CPC H05K 1/181; H10D 80/30; H10W 70/611; H10W 70/65; H10W 90/00; H10W 90/401; H05K 2201/10734; H10B 80/00; H10W 44/601; H10W 72/248; H10W 90/722; H10W 90/724

(57) ABSTRACT

A semiconductor package includes: a substrate with first and second surfaces; a first semiconductor chip on the second surface, and including a third surface facing the second surface and a fourth surface; a second semiconductor chip configured to operate based on a first power supply voltage, and including a fifth surface and a sixth surface, wherein the fifth surface faces the second surface and the sixth surface faces the first surface; a first PMIC on the second surface and configured to generate the first power supply voltage, provide the first power supply voltage to the second semiconductor chip, and including a seventh surface facing the second surface and an eighth surface opposite to the seventh surface in the first direction; first connecting terminals on the fifth surface; second connecting terminals on the third surface; and third connecting terminals on the seventh surface.

### CROSS-REFERENCE TO RELATED APPLICATION

This application claims priority to and the benefit under 35 U.S. C. § 119(a)-(d) of Korean Patent Application No. 10-2024-0117837, filed on Aug. 30, 2024, in the Korean Intellectual Property Office, the disclosure of which is incorporated by reference herein in its entirety.

### BACKGROUND

### 1. Field

The present disclosure relates to a semiconductor package.

### 2. Description of Related Art

With the rapid advancement of the electronics industry and the increasing demands from users, semiconductor packages mounted on electronic devices there is a need for further miniaturization, enhanced performance, and increased capacity. To achieve this, research and development of semiconductor packages that include both logic semiconductor chips and memory semiconductor chips are being conducted.

For the interface between semiconductor chips mounted on a semiconductor package, a Universal Chiplet Interconnect Express (UCIe) die is used, and a bridge die can be used for UCIe. However, because manufacturing a bridge die separately incurs additional costs and complexity, research is underway on methods for directly connecting semiconductor chips mounted on a semiconductor package.

### SUMMARY

One or more example embodiments provide a semiconductor package with reduced manufacturing costs, complexity and an improved form factor.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of an example embodiment, a semiconductor package includes: a substrate including a first surface and a second surface that are opposite to each other in a first direction; a first semiconductor chip on the second surface, and including a third surface facing the second surface and a fourth surface opposite to the third surface in the first direction; a second semiconductor chip mounted within the substrate, wherein the second semiconductor chip is configured to operate based on a first power supply voltage, and includes a fifth surface and a sixth surface that are opposite to each other in the first direction, the fifth surface faces the second surface and the sixth surface faces the first surface; a first power management integrated circuit (PMIC) on the second surface, wherein the first PMIC is configured to generate the first power supply voltage, provide the first power supply voltage to the second semiconductor chip, and includes a seventh surface facing the second surface and an eighth surface opposite to the seventh surface in the first direction; first connecting terminals provided on the fifth surface; second connecting terminals provided on the third surface; and third connecting terminals provided on the seventh surface. A first plurality of the first connecting terminals are in contact with at least some of the second connecting terminals, and a second plurality of the first connecting terminals are in contact with at least some of the third connecting terminals.

According to another aspect of an example embodiment, a semiconductor package includes: a substrate including a first surface and a second surface that are opposite to each other in a first direction; a first semiconductor chip disposed on the second surface, and including a third surface facing the second surface and a fourth surface opposite to the third surface in the first direction; a second semiconductor chip disposed on the second surface, wherein the second semiconductor chip is configured to operate based on a power supply voltage, and includes a fifth surface and a sixth surface that are opposite to each other in the first direction, the fifth surface faces the third surface and the sixth surface faces the second surface; a PMIC on the second surface, wherein the PMIC is configured to generate the power supply voltage, provide the power supply voltage to the second semiconductor chip, and includes a seventh surface facing the fifth surface and an eighth surface opposite to the seventh surface in the first direction; and first connecting terminals provided on the fifth surface. A first plurality of the first connecting terminals are provided on the third surface, and a second plurality of the first connecting terminals are provided on the seventh surface.

According to another aspect of an example embodiment, a semiconductor package includes: a substrate including a first surface and a second surface that are opposite to each other in a first direction; a first semiconductor chip on the second surface, and including a third surface facing the second surface and a fourth surface opposite to the third surface in the first direction; a second semiconductor chip including a fifth surface and a sixth surface that are opposite to each other in the first direction, wherein the second semiconductor chip is configured to operate based on a power supply voltage; and a PMIC on the second surface. The PMIC is configured to generate the power supply voltage, provide the power supply voltage to the second semiconductor chip, and includes a seventh surface facing the second surface and an eighth surface opposite to the seventh surface in the first direction. At least a first portion of the second semiconductor chip overlaps the first semiconductor chip along the first direction, and at least a second portion of the second semiconductor chip overlaps the PMIC along the first direction.

It should be noted that the effects of the present disclosure are not limited to those described above, and other effects of the present disclosure will be apparent from the following description.

### BRIEF DESCRIPTION OF DRAWINGS

The above and other aspects and features will be more apparent from the following description of example embodiments, taken in conjunction with the accompanying drawings, in which:

FIG. 1 is a plan view illustrating a semiconductor package according to some example embodiments;

FIG. 2 is a cross-sectional view taken along line I-I of FIG. 1 according to some example embodiments;

FIG. 3 is a diagram for explaining a semiconductor package according to some example embodiments;

FIG. 4 is a diagram for explaining a semiconductor package according to some example embodiments;

FIG. 5 is a diagram for explaining a semiconductor package according to some example embodiments;

FIG. 6 is a diagram for explaining a semiconductor package according to some example embodiments;

FIG. 7 is a diagram for explaining a semiconductor package according to some example embodiments;

FIG. 8 is a plan view for explaining a semiconductor package according to some example embodiments;

FIG. 9 is a cross-sectional view taken along line II-II of FIG. 8 according to some example embodiments;

FIG. 10 is a plan view for explaining a semiconductor package according to some example embodiments;

FIG. 11 is a cross-sectional view taken along line III-III of FIG. 10 according to some example embodiments;

FIG. 12 is a plan view for explaining a semiconductor package according to some example embodiments according to some example embodiments;

FIG. 13 is a cross-sectional view taken along line IV-IV of FIG. 12 according to some example embodiments;

FIG. 14 is a plan view for explaining a semiconductor package according to some example embodiments according to some example embodiments;

FIG. 15 is a cross-sectional view taken along line V-V of FIG. 14 according to some example embodiments;

FIG. 16 is a plan view for explaining a semiconductor package according to some example embodiments according to some example embodiments;

FIG. 17 is a cross-sectional view taken along line VI-VI of FIG. 16 according to some example embodiments;

FIG. 18 is a plan view for explaining a semiconductor package according to some example embodiments according to some example embodiments;

FIG. 19 is a cross-sectional view taken along line VII-VII of FIG. 18 according to some example embodiments;

FIG. 20 is a diagram for explaining a semiconductor package according to some example embodiments according to some example embodiments;

FIG. 21 is a diagram for explaining a semiconductor package; and

FIG. 22 is a diagram for explaining a semiconductor package according to some example embodiments.

### DETAILED DESCRIPTION

Hereinafter, example embodiments will be described with reference to the accompanying drawings. Like components are denoted by like reference numerals throughout the specification, and repeated descriptions thereof are omitted. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

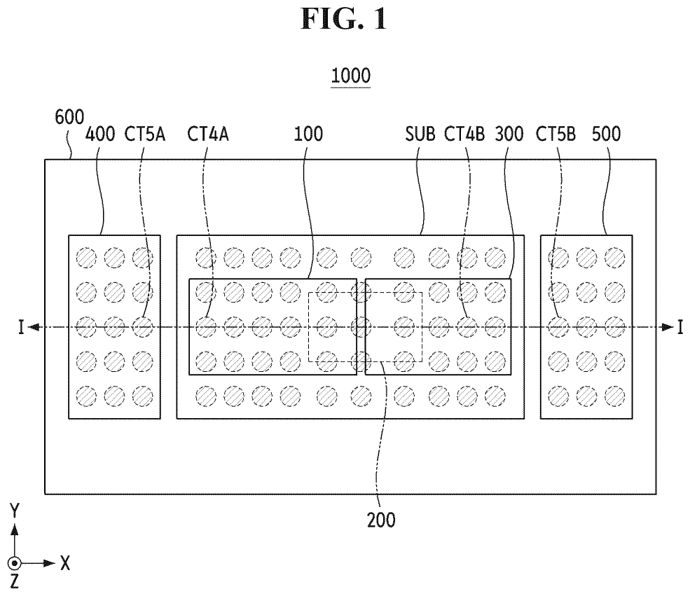

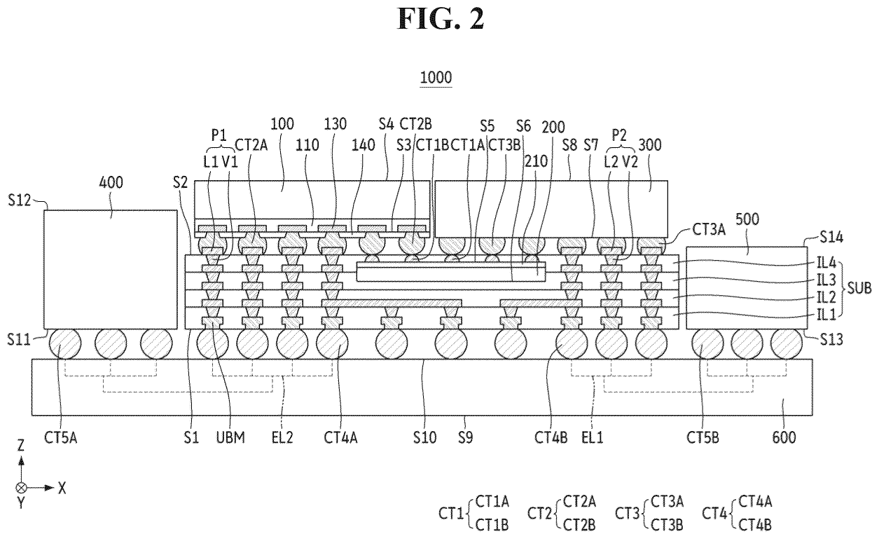

FIG. 1 is a plan view illustrating a semiconductor package according to some example embodiments. FIG. 2 is a cross-sectional view taken along line I-I of FIG. 1.

Referring to FIGS. 1 and 2, a semiconductor package 1000 may include a board 600, a substrate SUB, a semiconductor chip 100, a semiconductor chip 200, power management integrated circuits (PMICs) 300, 400, and 500, and connecting terminals (CT1, CT2, CT3, CT4, and CT5).

In the following description, a first direction Z, a second direction X, and a third direction Y may intersect each other. For example, the first direction Z, the second direction X, and the third direction Y may be orthogonal to each other. In addition, in the following description, the term “upper” may refer to the first direction Z, and the term “lower” may refer to the opposite direction of the first direction Z. For example, the term “upper surface” may be based on the first direction Z, and the term “lower surface” may be based on the opposite direction of the first direction Z. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

The board 600 may include surfaces S9 and S10 that are opposite to each other in the first direction Z. The surface S9 may be the lower surface of the board 600, and the surface S10 may be the upper surface of the board 600. The board 600 may be, for example, a printed circuit board (PCB) or a flexible printed circuit board (FPCB). A semiconductor package including the semiconductor chips 100 and 200 may be mounted on the board 600. Additionally, the PMICs 300, 400, and 500, which supply power to the semiconductor chips 100 and 200, may be mounted on the board 600.

The substrate SUB may be electrically connected to the board 600. For example, the substrate SUB may include a redistribution layer (RDL), a PCB, or an FPCB. The substrate SUB may include surfaces S1 and S2 that are opposite to each other in the first direction Z. The surface S1 may be the lower surface of the substrate SUB, and the surface S2 may be the upper surface of the substrate SUB. The substrate SUB may be mounted on the board 600 such that the surface S1 faces the surface S10 of the board 600.

The substrate SUB may include glass or organic material. Accordingly, as illustrated in FIG. 2, the semiconductor chip 200 may be mounted within the substrate SUB.

The substrate SUB may include first through fourth insulating films IL1 through IL4 and first patterns P1. The first insulating film IL1 may include an insulating polymer or a photoimageable dielectric (PID). For example, the PID may include at least one of a photosensitive polyimide, polybenzoxazole (PBO), a phenolic polymer, or a benzocyclobutene (BCB)-based polymer.

The first insulating film IL1 may be the lowermost layer among the first through fourth insulating films IL1 through IL4 included in the substrate SUB. Under-bump patterns UBM may be disposed within the first insulating film IL1. The under-bump patterns UBM may include a conductive material, for example, copper (Cu). The first insulating film IL1 may have first via portions V1 that are disposed within the first insulating film IL1. The first via portion V1 may include a conductive material, such as Cu. The under-bump patterns UBM within the first insulating film IL1 may be connected to configurations attached to the surface S10 of the board 600. For example, the under-bump patterns UBM may be connected to connecting terminals CT4, respectively.

A plurality of first patterns P1 may be provided. As illustrated in FIG. 2, each of the first patterns P1 may include a first wiring portion L1 and a first via portion V1. The first via portions V1 of the first patterns P1 may be disposed within the first insulating film IL1. As used herein, the via portion of a conductive component may be for a vertical connection (for example, in the first direction Z), and the wiring portion of a conductive component may be for a horizontal connection (for example, in the second direction X or the third direction Y). In this case, the width of the wiring portion may be greater than the width of the via portion.

The first wiring portions L1 of the first patterns P1 may extend in a direction parallel to the surface S1 of the substrate SUB. The width of the first wiring portions L1 may be greater than the width of the first via portions V1. The first via portions V1 may be disposed below the first wiring portions L1. The first via portions V1 may have a shape protruding from the lower surfaces of the first wiring portions L1. The width of the tops of the first via portions V1 may be greater than the width of the bottoms of the first via portions V1. The first patterns P1 may include a conductive material. For example, the first patterns P1 may include at least one of Cu, tungsten (W), and titanium (Ti).

The substrate SUB may further include the second, third and, fourth insulating films IL2, IL3, and IL4, and the first patterns P1 may be disposed within each of the second, third, and fourth insulating films IL2, IL3, and IL4. The first patterns P1 may be electrically connected to the semiconductor chip 100 through connecting terminals CT2A.

The substrate SUB may include a plurality of second patterns P2. Each of the second patterns P2 may include a second wiring portion L2 and a second via portion V2. The second pattern P2 may be electrically connected to the PMIC 300 through connecting terminals CT3A. The description of the second patterns P2 overlaps with the description of the first patterns P1, and thus, repeated description of the second patterns P2 will be omitted.

The substrate SUB is illustrated as including four insulating films, i.e., the first through fourth insulating films IL1 through IL4, but example embodiments are not limited thereto. For example, the substrate SUB may include three or fewer insulating films, or five or more insulating films, in which the first patterns P1 and the second patterns P2 are provided.

The connecting terminals CT4 may be used to connect the substrate SUB to the board 600. The connecting terminals CT4 may include connecting terminals CT4A and connecting terminals CT4B. The connecting terminals CT4A may be connected to the semiconductor chip 100 through the first patterns P1, and the connecting terminals CT4B may be connected to the PMIC 300 through the second patterns P2. The connecting terminals CT4 may include an electrically conductive material such as a metal. For example, the connecting terminals CT4 may include at least one of lead (Pb), tin (Sn), silver (Ag), gold (Au), Cu, or aluminum (Al). The connecting terminals CT4 may be, for example, solder bumps, Au bumps, or Cu bumps.

The semiconductor chip 100 may be disposed on the substrate SUB. The semiconductor chip 100 may include surfaces S3 and S4 that are opposite to each other in the first direction Z. The surface S3 of the semiconductor chip 100 may be disposed to face the surface S2 of the substrate SUB.

The semiconductor chip 100 may include a semiconductor device layer 110, connection pads 130, and a protective layer 140. The semiconductor chip 100 may include the semiconductor device layer 110 in a portion adjacent to the surface S3. The semiconductor device layer 110 may be provided in portions of the semiconductor chip 100 adjacent to the connection pads 130. The semiconductor device layer 110 may include a plurality of individual devices, and the plurality of individual devices may include different types of devices. For example, the plurality of individual devices may include various microelectronic devices, such as complementary metal-oxide-semiconductor (CMOS) transistors, metal-oxide-semiconductor field-effect transistors (MOSFETs), system large-scale integration (LSI) systems, CMOS imaging sensors (CISs), micro-electro-mechanical systems (MEMSs), active devices, and passive devices.

Thus, between the two surfaces S3 and S4 of the semiconductor chip 100 that are opposite to each other in the first direction Z, the surface S3 where the semiconductor device layer 110 is provided may be the front surface of the semiconductor chip 100, and the surface S4, which is opposite to the surface S3 where the semiconductor device layer 110 is provided, may be the back surface of the semiconductor chip 100.

The semiconductor chip 100 may include a logic semiconductor chip. The logic semiconductor chip may include, for example, a central processing unit (CPU), a micro-processor unit (MPU), a graphics processing unit (GPU), or an application processor (AP). Additionally, the semiconductor chip 100 may also include a memory semiconductor chip. The memory semiconductor chip may include, for example, a volatile memory semiconductor chip such as a dynamic random-access memory (DRAM) or a static random-access memory (SRAM), and may also include a non-volatile memory semiconductor chip such as a phase-change random-access memory (PRAM), a magneto-resistive random-access memory (MRAM), a ferroelectric random-access memory (FeRAM), or a resistive random-access memory (RRAM).

The connection pads 130 of the semiconductor chip 100 may be disposed on the surface S3. The connection pads 130 may be pads that are electrically connected to the plurality of individual devices within the semiconductor device layer 110 of the semiconductor chip 100. A plurality of connection pads 130 may be provided on the semiconductor chip 100.

The connection pads 130 may include Al, but example embodiments are not limited thereto. The material of the connection pads 130 may include a metal such as N), Cu, Au, Ag, W, Ti, tantalum (Ta), indium (In), molybdenum (Mo), manganese (Mn), cobalt (Co), Sn, magnesium (Mg), rhenium (Re), beryllium (Be), gallium (Ga), ruthenium (Ru), or an alloy thereof.

The protective layer 140 may be disposed on the surface S3 of the semiconductor chip 100. The protective layer 140 may cover the surface S3 of the semiconductor chip 100 to protect the semiconductor chip 100. For example, as illustrated in FIG. 2, the protective layer 140 may be cover the entire surface S3 of the semiconductor chip 100, excluding the areas where the connection pads 130 are provided.

The protective layer 140 may be a layer of an insulating material and may include an oxide or a nitride. For example, the protective layer 140 may include silicon oxide or silicon nitride. Additionally, the protective layer 140 may include an insulating material of a PID material that is compatible with a photolithography process. For example, the protective layer 140 may include a photosensitive polyimide (PSPI).

One or more portions of the connection pads 130 may not be surrounded by the protective layer 140 and may be exposed through the protective layer 140. Portions of the lower surfaces of the connection pads 130 that are exposed through the protective layer 140 may contact the connecting terminals CT2.

The connecting terminals CT2 may be disposed between the semiconductor chip 100 and the substrate SUB. The connecting terminals CT2 may be attached to the surface S3 of the semiconductor chip 100. The connecting terminals CT2 may include connecting terminals CT2A and connecting terminals CT2B. Upper portions of the connecting terminals CT2A may contact the connection pads 130 and the protective layer 140, and lower portions of the connecting terminals CT2A may contact the first wiring portions L1. The connecting terminals CT2A may be terminals of a conductive material that electrically connect the substrate SUB and the semiconductor chip 100.

Upper portions of the connecting terminals CT2B may contact the connection pads 130 and the protective layer 140, and lower portions of the connecting terminals CT2B may contact connecting terminals CT1B. The connecting terminals CT2A may be terminals of a conductive material that electrically connect the substrate SUB and the semiconductor chip 100, and the connecting terminals CT2B may be terminals of a conductive material that electrically connect the semiconductor chip 100 and the semiconductor chip 200.

For example, the connecting terminals CT2 may include at least one of Pb, Sn, Ag, Au, Cu, or Al. The connecting terminals CT2 may be, for example, solder bumps, Au bumps, or Cu bumps.

The semiconductor chip 200 may be mounted within the substrate SUB. That is, as illustrated in FIG. 2, the semiconductor chip 200 may be embedded within the substrate SUB. The semiconductor chip 200 may include surfaces S5 and S6 that are opposite to each other in the first direction Z. The surface S5 of the semiconductor chip 200 may be disposed to face the surface S2 of the substrate SUB, and the surface S6 of the semiconductor chip 200 may be disposed to face the surface S1 of the substrate SUB.

The semiconductor chip 200 may include a semiconductor device layer 210 in a portion adjacent to the surface S5. The semiconductor device layer 210 may include various types of individual devices. For example, the semiconductor device layer 210 may include various microelectronic devices, such as CMOS transistors, MOSFETs, LSI systems, CISs, MEMSs, active devices, and passive devices.

Thus, between the two surfaces S5 and S6 of the semiconductor chip 200 that are opposite to each other in the first direction Z, the surface S5 where the semiconductor device layer 210 is provided may be the front surface of the semiconductor chip 200, and the surface S6, which is opposite to the surface S5 where the semiconductor device layer 210 is provided, may be the back surface of the semiconductor chip 200. That is, the semiconductor chips 100 and 200 may be connected in a front-to-front configuration such that their front sides face each other through the connecting terminals CT2B and the connecting terminals CT1B.

The semiconductor chip 200 may include a logic semiconductor chip. The logic semiconductor chip may include, for example, a CPU, an MPU, a GPU, or an AP. Additionally, the semiconductor chip 200 may also include a memory semiconductor chip. The memory semiconductor chip may include, for example, a volatile memory semiconductor chip such as a DRAM or an SRAM, and may also include a non-volatile memory semiconductor chip such as a PRAM, an MRAM, an FeRAM, or an RRAM.

The connecting terminals CT1 may be attached to the surface S5 of the semiconductor chip 200. The connecting terminals CT1 may include connecting terminals CT1A and connecting terminals CT1B. Lower portions of the connecting terminals CT1A may be connected to the semiconductor device layer 210, and upper portions of the connecting terminals CT1A may contact the connecting terminals CT3B. Additionally, lower portions of the connecting terminals CT1B may be connected to the semiconductor device layer 210, and upper portions of the connecting terminals CT1B may contact the connecting terminals CT2B.

For example, the upper portions of the connecting terminals CT1A may be exposed to the outside from the surface S2 of the substrate SUB, and the exposed upper portions of the connecting terminals CT1A may contact lower portions of the connecting terminals CT3B. Similarly, the upper portions of the connecting terminals CT1B may be exposed to the outside from the surface S2 of the substrate SUB, and the exposed upper portions of the connecting terminals CT1B may contact the lower portions of the connecting terminals CT2B.

The connecting terminals CT1A may be terminals of a conductive material that electrically connect the semiconductor chip 200 and the PMIC 300, and the connecting terminals CT1B may be terminals of a conductive material that electrically connect the semiconductor chips 100 and 200.

For example, the connecting terminals CT1 may include at least one of Pb, Sn, Ag, Au, Cu, or Al. The connecting terminals CT1 may be, for example, solder bumps, Au bumps, or Cu bumps.

Signals generated in the semiconductor chip 200 may be transmitted outside of the semiconductor package 1000 (i.e., to an external component) via the connecting terminals CT1A, the connecting terminals CT3B, the PMIC 300, the connecting terminals CT3A, the second patterns P2, the connecting terminals CT4B, and the board 600. Additionally, signals provided from outside the semiconductor package 1000 to the semiconductor chip 200 may be delivered to the semiconductor chip 200 in reverse order.

The PMIC 300 may generate a first power supply voltage based on an input voltage and provide the generated first power supply voltage to the semiconductor chip 200. The PMIC 300 may include surfaces S7 and S8 that are opposite to each other in the first direction Z. The PMIC 300 may be mounted on the surface S2 of the substrate SUB. The surface S7 of the PMIC 300 may be disposed to face the surface S2 of the substrate SUB.

The connecting terminals CT3 may be disposed between the PMIC 300 and the substrate SUB. The connecting terminals CT3 may be attached to the seventh surface S7 of the PMIC 300. The connecting terminals CT3 may include connecting terminals CT3A and connecting terminals CT3B. Upper portions of the connecting terminals CT3A may be attached to the surface S7 of the PMIC 300, and lower portions of the connecting terminals CT3A may contact the second wiring portions V2.

Upper portions of the connecting terminals CT3B may be attached to the surface S7 of the PMIC 300, and lower portions of the connecting terminals CT3B may contact the connecting terminals CT1A. The connecting terminals CT3A may be terminals of a conductive material that electrically connect the PMIC 300 and the substrate SUB, and the connecting terminals CT3B may be terminals of a conductive material that electrically connect the PMIC 300 and the semiconductor chip 200. That is, the PMIC 300 may provide the first power supply voltage to the semiconductor chip 200 through the connecting terminals CT3B and the connecting terminals CT1A.

For example, the connecting terminals CT3 may include at least one of Pb, Sn, Ag, Au, Cu, or Al. The connecting terminals CT3 may be, for example, solder bumps, Au bumps, or Cu bumps.

The PMIC 400 may generate a second power supply voltage based on the input voltage and provide the generated second power supply voltage to the semiconductor chip 100. The PMIC 400 may be configured to generate more power than the PMIC 300. The second power supply voltage generated by the PMIC 400 may be different than the first power supply voltage generated by the PMIC 300. The PMIC 400 may include surfaces S11 and S12 that are opposite to each other in the first direction Z. The PMIC 400 may be mounted on the surface S10 of the board 600. The surface S11 of the PMIC 400 may be disposed to face the surface S10 of the board 600.

The connecting terminals CT5A may be disposed between the PMIC 400 and the board 600. The connecting terminals CT5A may connect to the connecting terminals CT4A via wiring patterns EL2 within the board 600. That is, the PMIC 400 may provide the second power supply voltage to the semiconductor chip 100 through the connecting terminals CT5A, the wiring patterns EL2, the connecting terminals CT4A, the first patterns P1, and the connecting terminals CT2A.

The PMIC 500 may generate a third power supply voltage based on the input voltage and provide the generated third power supply voltage to the semiconductor chip 200. The PMIC 500 may be configured to generate more power than the PMIC 300. The third power supply voltage generated by the PMIC 500 may be different than the first power supply voltage generated by the PMIC 300. The second power supply voltage generated by the PMIC 400 may be the same or different than the third power supply voltage generated by the PMIC 500. The PMIC 500 may include surfaces S13 and S14 that are opposite to each other in the first direction Z. The PMIC 500 may be mounted on the surface S10 of the board 600. The surface S13 of the PMIC 500 may be disposed to face the surface S10 of the board 600.

The connecting terminals CT5B may be disposed between the PMIC 500 and the board 600. The connecting terminals CT5B may connect to the connecting terminals CT4B via wiring patterns EL1 within the board 600. That is, the PMIC 500 may provide the third power supply voltage to the semiconductor chip 200 through the connecting terminals CT5B, the wiring patterns EL1, the connecting terminals CT4B, the second patterns P2, CT3A, the PMIC 300, the connecting terminals CT3B, and the connecting terminals CT1A. In this regard, the semiconductor chip 200 may operate based on the first power supply voltage provided by the PMIC 300 and the third power supply voltage provided by the PMIC 500.

In the semiconductor package 1000, the semiconductor chip 200 may be mounted within the substrate SUB, with the semiconductor chips 100 and 200 connected in a front-to-front configuration. The PMICs 300 and 500 may both provide power supply voltages to the semiconductor chip 200. The PMIC 300 may be mounted on the substrate SUB, whereas the PMIC 500 may be mounted on the board 600. Accordingly, as two PMICs are both providing a power supply voltage to the semiconductor chip 200, the size of the PMIC 500 mounted on the board 600 may be smaller than a contrasting example in which the PMIC 300 is not provided. Therefore, the area occupied by the PMIC that supplies a power supply voltage to the semiconductor chip 200 on the board 600 may be reduced, thereby decreasing the form factor.

In addition, as the semiconductor chips 100 and 200 are connected in a front-to-front configuration, a bridge die for interconnecting the semiconductor chips 100 and 200 in the semiconductor package 1000 is not needed, which can reduce the manufacturing cost for the bridge die and complexity.

Furthermore, because the semiconductor chip 200 and the PMIC 300, which provides a power supply voltage to the semiconductor chip 200, are configured in the same semiconductor package, the connection distance between the PMIC 300 and the semiconductor chip 200 is shortened, which can improve the power delivery network (PDN).

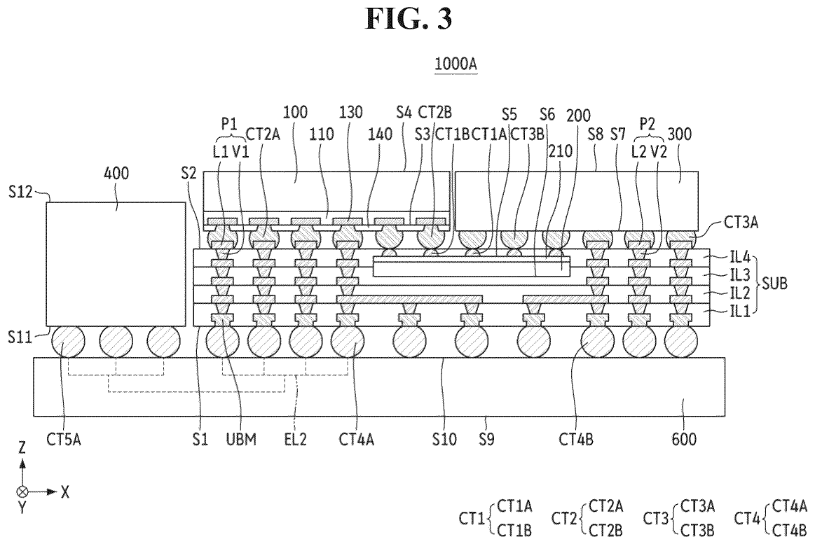

FIG. 3 is a diagram for explaining a semiconductor package according to some example embodiments. The following description will focus on the differences, omitting repeated explanations.

Referring to FIG. 3, unlike the semiconductor package 1000 in FIGS. 1 and 2, a semiconductor package 1000A may not include a PMIC 500. That is, only a PMIC 300 mounted on a substrate SUB may supply power to a semiconductor chip 200. Accordingly, the semiconductor chip 200 may operate based solely on the power supply voltage provided by the PMIC 300.

As a result, the area occupied by the PMIC 500 that provides a power supply voltage to the semiconductor chip 200 on a board 600 is not necessary, and therefore the board 600 may have a smaller size, further enhancing the effect of reducing the form factor.

In some example embodiments, the power required for the operation of a semiconductor chip 100 may be greater than that required for the operation of the semiconductor chip 200. Additionally, the heat generated by the semiconductor chip 200 during operation may be relatively lower than the heat generated by the semiconductor chip 100 during operation. Accordingly, a PMIC 400 that provides a power supply voltage to the semiconductor chip 100 may by mounted horizontally on the board 600, rather than on the substrate SUB. In contrast, the semiconductor chip 200, with its lower power consumption and heat generation, may be mounted within the substrate SUB, and the PMIC 300 that provides a power supply voltage to the semiconductor chip 200 may be vertically stacked on the substrate SUB. Accordingly, the effects of reducing the form factor and improving the PDN can be provided.

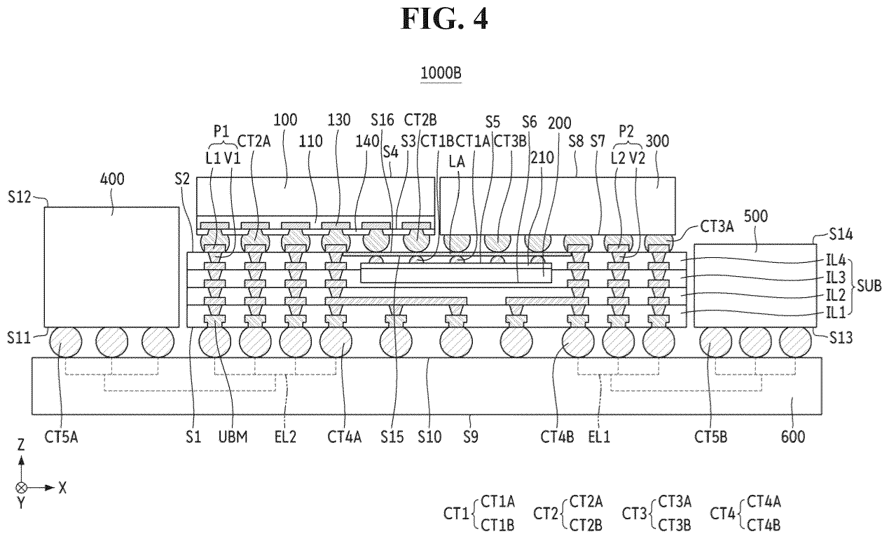

FIG. 4 is a diagram for explaining a semiconductor package according to some example embodiments.

Referring to FIG. 4, a semiconductor package 1000B may further include a metal layer LA. The metal layer LA may include surfaces S15 and S16 that are opposite to each other in the first direction Z. As illustrated in FIG. 4, the metal layer LA may be mounted within the substrate SUB. For example, the surface S16 of the metal layer LA may be coplanar with the surface S2 of the substrate S2. Alternatively, the metal layer LA may be disposed on the surface S2 of the substrate SUB, and the surface S16 of the metal layer LA may be offset from the surface S2 of the substrate S2 in the first direction Z.

Connection terminals CT3B and connecting terminals CT2B may contact the surface S16 of the metal layer LA. Additionally, connecting terminals CT1 may contact the surface S15 of the metal layer LA. The metal layer LA may include a conductive material. The metal layer LA may extend in the second direction X and may be electrically connected to first via portions V1 and second via portions V2. Accordingly, signals generated in a semiconductor chip 200 may be transmitted outside of the semiconductor package 1000B through the metal layer LA. Furthermore, signals provided from outside the semiconductor package 1000B to the semiconductor chip 200 may be transmitted through the metal layer LA.

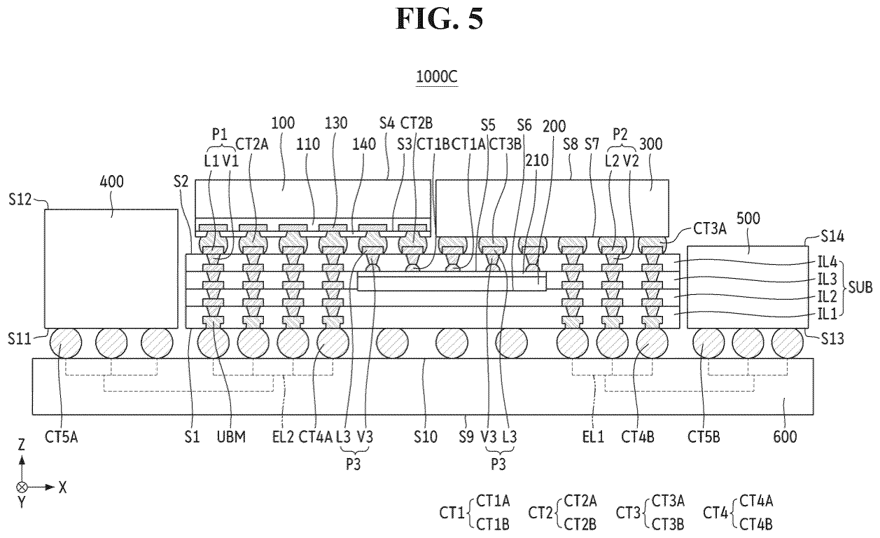

FIG. 5 is a diagram for explaining a semiconductor package according to some example embodiments.

Referring to FIG. 5, a substrate SUB of a semiconductor package 1000C may further include third patterns P3. A plurality of third patterns P3 may be provided within a substrate SUB. Each of the third patterns P3 may include a third wiring portion L3 and a third via portion V3. The third via portions V3 of the third patterns P3 may be disposed within a fourth insulating film IL4.

The third wiring portions L3 of the third patterns P3 may extend in a direction parallel to a surface S2 of the substrate SUB. The width of the third wiring portions L3 may be greater than the width of the third via portions V3. The third via portions V3 may be disposed below the third wiring portions L3. The third via portions V3 may have a shape protruding from the lower surfaces of the third wiring portions L3. The width of the tops of the third via portions V3 may be greater than the width of the bottoms of the third via portions V3. The third patterns P3 may include a conductive material. For example, the third patterns P3 may include at least one of Cu, W, and Ti.

The third wiring portions L3 may be disposed on the surface S2 of the substrate SUB. Some of the third wiring portions L3 may contact connecting terminals CT2B, and other third wiring portions L3 may contact connecting terminals CT3B. Upper portions of the third via portions V3 may contact the third wiring portions L3, and lower portions of the third via portions V3 may contact connecting terminals CT1. Accordingly, semiconductor chips 100 and 200 may be electrically connected to each other through connecting terminals CT1B, the third via portions V3, the third wiring portions L3, and the connecting terminals CT2B. Furthermore, the semiconductor chip 200 and a PMIC 300 may be electrically connected to each other through connecting terminals CT1A, the third via portions V3, the third wiring portions L3, and the connecting terminals CT3B.

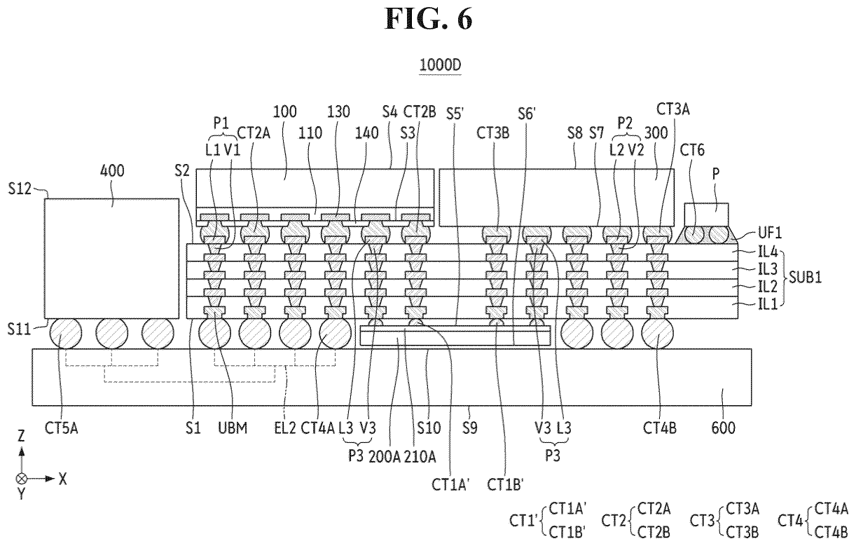

FIG. 6 is a diagram for explaining a semiconductor package according to some example embodiments.

Referring to FIG. 6, a semiconductor package 1000D may include a substrate SUB1, a semiconductor chip 200A, and a passive element P. Unlike the substrates SUB of FIGS. 1 through 5, the substrate SUB1 may include silicon (Si). Therefore, the semiconductor chip 200A may not be mounted within the substrate SUB1, whereas the semiconductor chip 200 discussed above with reference to FIGS. 1 through 5 is mounted within the substrate SUB. Accordingly, in the semiconductor package 1000D, the semiconductor chip 200A may be disposed on a surface S1 of the substrate SUB1.

The semiconductor chip 200A may include surfaces S5′ and S6′ that are opposite to each other in the first direction Z. The surface S5′ of the semiconductor chip 200A may be disposed to face the surface S1 of the substrate SUB1, and the surface S6′ of the semiconductor chip 200A may be disposed to face a surface S10 of a board 600. That is, the semiconductor chip 200A may be disposed between the substrate SUB1 and the board 600.

The semiconductor chip 200A may include a semiconductor device layer 210A in a portion adjacent to the surface S5′. The description of the semiconductor device layer 210A overlaps with the description of the semiconductor device layer 110, and thus, repeated description of the semiconductor device layer 210A will be omitted.

The surface S5′ of the semiconductor chip 200A may be the front surface of the semiconductor chip 200A, and the surface S6′ of the semiconductor chip 200A may be the back surface of the semiconductor chip 200A. In this regard, a semiconductor chip 100 and the semiconductor chip 200A may be connected in a front-to-front configuration.

Connection terminals CT1′ may be attached to the surface S5′ of the semiconductor chip 200A. The connecting terminals CT1′ may include connecting terminals CT1A′ and connecting terminals CT1B′. Lower portions of the connecting terminals CT1A′ may be connected to the semiconductor device layer 210A, and upper portions of the connecting terminals CT1A′ may contact under-bump patterns UBM that are connected to first patterns P1. Similarly, lower portions of the connecting terminals CT1B′ may be connected to the semiconductor device layer 210A, and upper portions of the connecting terminals CT1B′ may contact under-bump patterns UBM that are connected to second patterns P2.

The semiconductor chip 200A may be connected to the semiconductor chip 100 through the connecting terminals CT1A′ and the first patterns P1 and may thus exchange signals with the semiconductor chip 100. Additionally, the semiconductor chip 200A may be connected to a PMIC 300 through the connecting terminals CT1B′ and the second patterns P2 and may thus receive the third power supply voltage generated by the PMIC 300.

The passive element P may be disposed on the surface S2 of the substrate SUB1. The passive element P may include a connection surface facing the substrate SUB1, a non-connection surface opposite to the connection surface in the first direction Z, and side surfaces between the connection and non-connection surfaces. Here, the non-connection surface may refer to the surface of the passive element P that is exposed to the outside of the semiconductor package 1000D, located opposite the surface facing the substrate SUB1. For example, the connection surface may be the lower surface of the passive element P, and the non-connection surface may be the upper surface of the passive element P.

The passive element P may include, for example, a capacitor, an inductor, or beads. For example, the passive element P may be a chip-type Si capacitor with high electrical capacity. The connection surface of the passive element P may include connecting terminals CT6. The connecting terminals CT6 of the passive element P may be configured to electrically connect the passive element P to the substrate SUB1 and may include a conductive material. A plurality of connecting terminals CT6 may be provided between the passive element P and the substrate SUB1. Upper portions of the connecting terminals CT6 may contact connection terminals disposed on the connection surface of the passive element P, and lower portions of the connecting terminals CT6 may contact conductive patterns disposed within the substrate SUB1. The connecting terminals CT6 may electrically connect the connection terminals of the passive element P to the conductive patterns within the substrate SUB1.

An underfill film UF1 may be disposed between the passive element P and the substrate SUB1. The semiconductor chip 100 may be spaced apart from the PMIC 300. The underfill film UF1 may electrically insulate the passive element P from the semiconductor chip 100 and the PMIC 300. The underfill film UF1 may cover the entire connection surface of the passive element P, a portion of the surface S2 of the substrate SUB1, and the connecting terminals CT6. The underfill film UF1 may include an insulating resin, such as an epoxy molding compound (EMC).

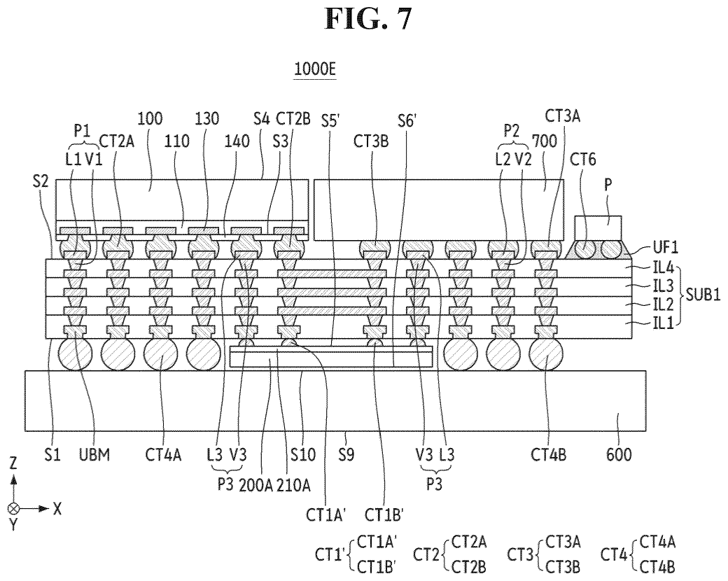

FIG. 7 is a diagram for explaining a semiconductor package according to some example embodiments.

Referring to FIG. 7, a PMIC 700 may generate a fourth power supply voltage based on an input voltage and provide the generated fourth power supply voltage to both semiconductor chips 100 and 200. The semiconductor chips 100 and 200 may each operate based on the fourth power supply voltage provided by the PMIC 700.

In a semiconductor package 1000E, as the PMIC 700 that provides a power supply voltage to the semiconductor chips 100 and 200 is mounted on a substrate SUB, the area occupied on a board 600 by a PMIC that solely provides a power supply voltage to the semiconductor chip 100, as in the semiconductor package 1000D of FIG. 6 is not necessary, and therefore the board 600 may have a smaller size. Therefore, the form factor of the semiconductor package 1000E can be reduced.

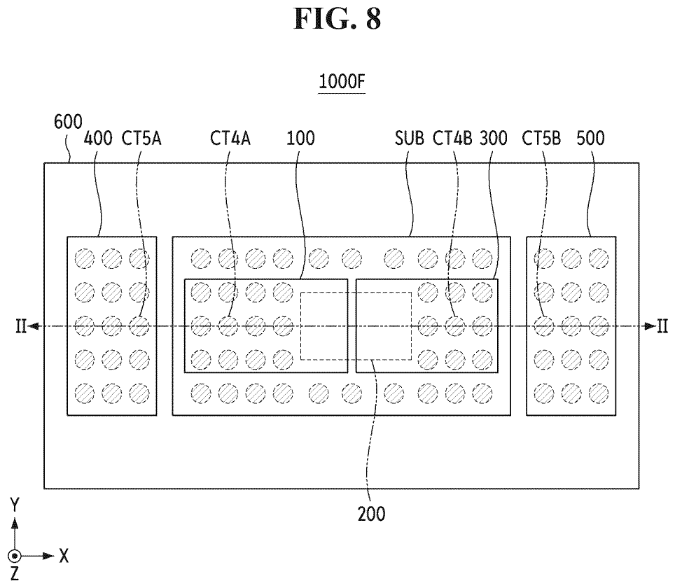

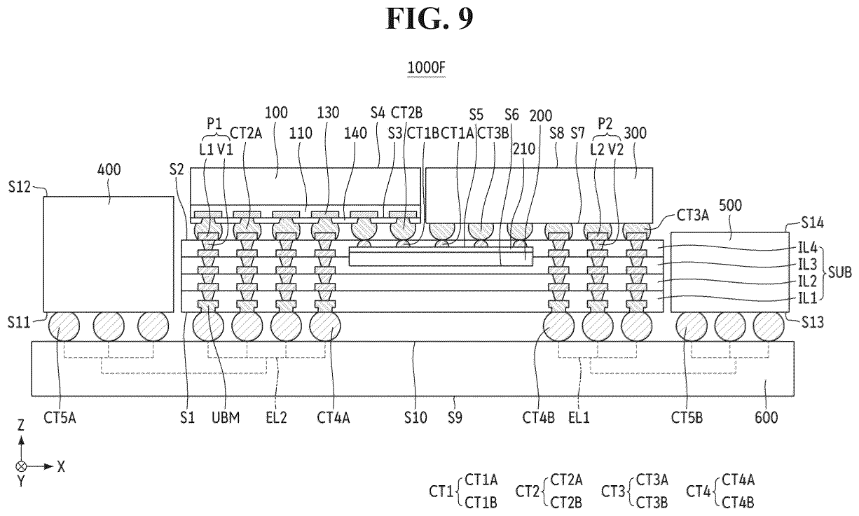

FIG. 8 is a plan view for explaining a semiconductor package according to some example embodiments. FIG. 9 is a cross-sectional view taken along line II-II of FIG. 8.

Referring to FIGS. 8 and 9, in a plan view, the region where connecting terminals CT4 attached to a surface S1 of a substrate SUB are disposed may not overlap with the region where a semiconductor chip 200 mounted within the substrate SUB is disposed. That is, because a semiconductor chip 100 and the semiconductor chip 200 in a semiconductor package 1000F are connected in a front-to-front configuration, there may not be a need to place connecting terminals in the region where the lower part of the substrate SUB overlaps, in a plan view, with the semiconductor chip 200, to transmit signals or power to the semiconductor chip 200. Accordingly, the number of balls required to manufacture the semiconductor package 1000F can be reduced.

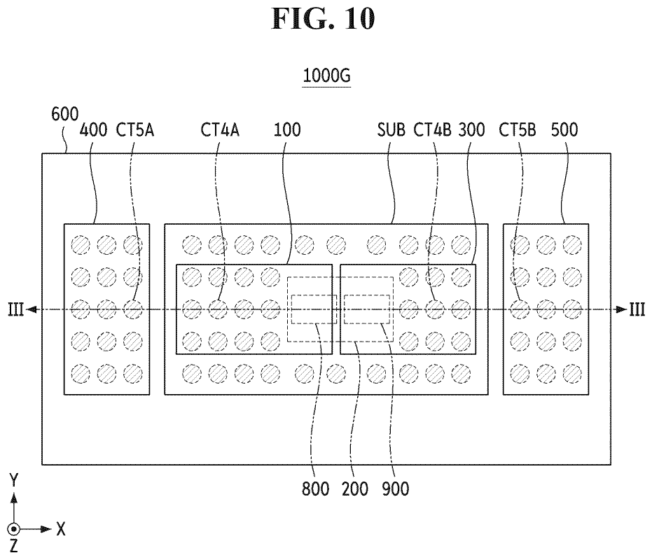

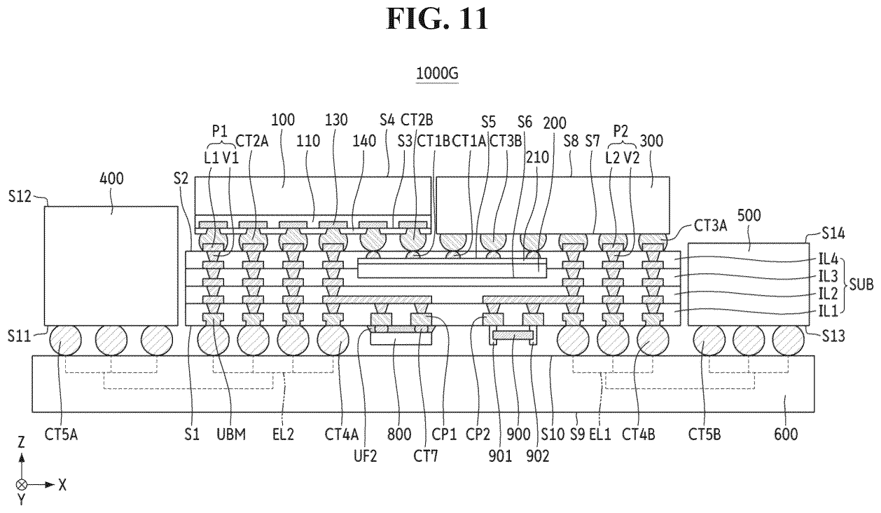

FIG. 10 is a plan view for explaining a semiconductor package according to some example embodiments. FIG. 11 is a cross-sectional view taken along line III-III of FIG. 10.

Referring to FIGS. 10 and 11, passive elements 800 and 900 may be attached to a surface S1 of a substrate SUB. The passive elements 800 and 900 may be disposed within the region where the surface S1 of the substrate SUB overlaps, in a plan view, with the region where a semiconductor chip 200 mounted within the substrate SUB is disposed.

The passive element 800 may include a connection surface facing the substrate SUB, a non-connection surface opposite to the connection surface in the first direction Z, and side surfaces between the connection and non-connection surfaces. Here, the non-connection surface may refer to the surface of the passive element 800 that is located opposite the surface facing the substrate SUB. For example, the connection surface may be the upper surface of the passive element 800, and the non-connection surface may be the lower surface of the passive element 800.

The passive element 800 may include, for example, a capacitor, an inductor, or beads. For example, the passive element 800 may be a chip-type Si capacitor with high electrical capacity. The connection surface of the passive element 800 may include connecting terminals CT7. The connecting terminals CT7 of the passive element 800 may be configured to electrically connect the passive element 800 to the substrate SUB and may include a conductive material. A plurality of connecting terminals CT7 may be provided between the passive element 800 and the substrate SUB. Lower portions of the connecting terminals CT7 may contact connection terminals disposed on the connection surface of the passive element 800, and upper portions of the connecting terminals CT7 may contact connection pattern CP1 disposed within the substrate SUB. The connecting terminals CT7 may electrically connect the connection terminals of the passive element 800 to the connection patterns CP1 within the substrate SUB.

The connection patterns CP1 may be disposed within a first insulating film IL1 and may include a conductive material. Upper portions of the connection patterns CP1 may contact first via portions V1. The connection patterns CP1 may be electrically connected to a semiconductor chip 100 through first patterns P1. The passive element 800 may be a passive element of the semiconductor chip 100, which has high power consumption.

An underfill film UF2 may be disposed between the passive element 800 and the substrate SUB and spaced apart from the passive element 800 and the connecting terminals CT7. The underfill film UF2 may electrically insulate the passive element 800 from the connecting terminals CT7. The underfill film UF2 may cover the entire connection surface of the passive element 800, a portion of the surface S1 of the substrate SUB, and the connecting terminals CT7. The underfill film UF2 may include an insulating resin, such as an EMC.

The passive element 900 may be disposed on the surface S1 of the substrate SUB. The passive element 900 may be, for example, a capacitor. For example, the passive element 900 may be an Si capacitor, a multilayer ceramic capacitor (MLCC), or a low inductance ceramic capacitor (LICC), but example embodiments are not limited thereto.

A first conductive pad 901 and a second conductive pad 902 may be disposed on the surface S1 of the substrate SUB. The first and second conductive pads 901 and 902 may protrude from the surface S1 of the substrate SUB. The first and second conductive pads 901 and 902 may each contact the sidewalls of the passive element 900 and may include a conductive material. For example, the first and second conductive pads 901 and 902 may be spaced apart from each other in the second direction X.

The first and second conductive pads 901 and 902 may be electrically connected to third connection patterns CP2 disposed within an insulating film IL1 and may be electrically connected to the passive element 900. That is, the first and second conductive pads 901 and 902 may electrically connect the substrate SUB and the passive element 900.

For example, the first and second conductive pads 901 and 902 may ground the passive element 900. Additionally, the first and second conductive pads 901 and 902 may supply power to the passive element 900. For example, the first conductive pad 901 may ground the passive element 900, and the second conductive pad 902 may supply power to the passive element 900. As another example, the second conductive pad 902 may ground the passive element 900, and the first conductive pad 901 may supply power to the passive element 900.

The connection patterns CP2 may be disposed within the first insulating film IL1 and may include a conductive material. Upper portions of the connection patterns CP2 may contact second via portions V2. The connection patterns CP2 may be electrically connected to a PMIC 300 through the second patterns P2. The passive element 900 may be a passive element of the PMIC 300, which has high power consumption.

As the semiconductor chips 100 and 200 in the semiconductor package 1000G are connected in a front-to-front configuration, there may not be a need to place connecting terminals in the region where the lower part of the substrate SUB overlaps in a plan view with the semiconductor chip 200, to transmit signals or power to the semiconductor chip 200. Accordingly, the passive element 800 of the semiconductor chip 100 and/or the passive element 900 of the PMIC 300 may be disposed within the region where the surface S1 of the substrate SUB overlaps, in a plan view, with the region where the semiconductor chip 200 mounted within the substrate SUB is disposed, thereby increasing the utilization of the lower area of the substrate SUB.

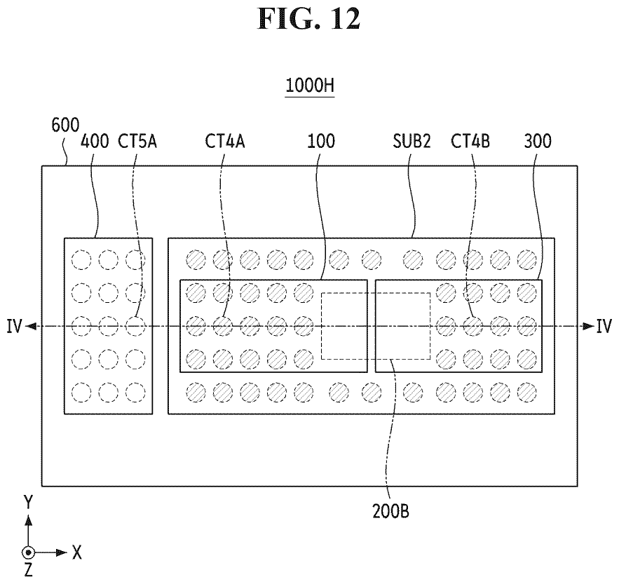

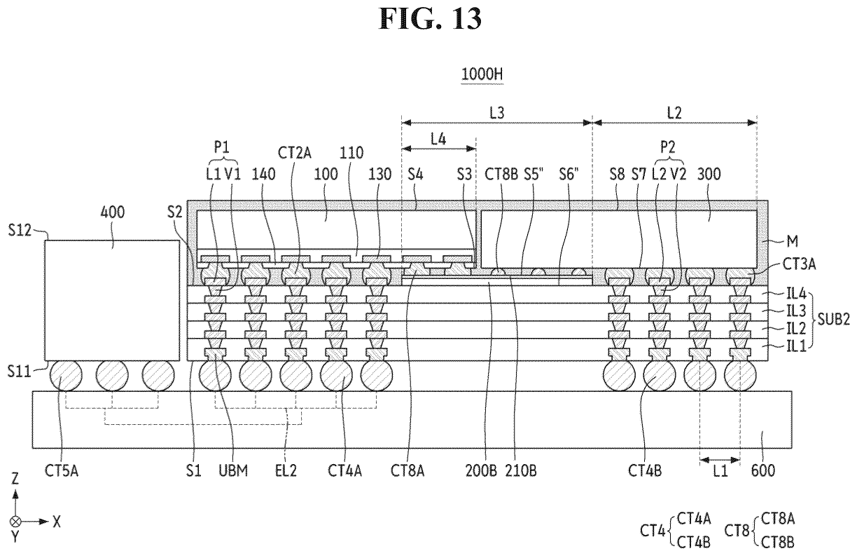

FIG. 12 is a plan view for explaining a semiconductor package according to some example embodiments. FIG. 13 is a cross-sectional view taken along line IV-IV of FIG. 12.

Referring to FIGS. 12 and 13, a semiconductor package 1000H may include a substrate SUB2, a semiconductor chip 200B, and a mold layer M. The substrate SUB2 may be a substrate that includes Si. Therefore, the semiconductor chip 200B may not be mounted within the substrate SUB2. Accordingly, in the semiconductor package 1000H, the semiconductor chip 200B may be disposed on the substrate SUB2.

The semiconductor chip 200B may include surfaces S5″ and S6″ that are opposite to each other in the first direction Z. The surface S5″ of the semiconductor chip 200B may be disposed to face a surface S3 of a semiconductor chip 100 and a surface S7 of a PMIC 300, and the surface S6″ of the semiconductor chip 200B may be disposed to face a surface S2 of the substrate SUB2. In this regard, the semiconductor chip 200B may be disposed between the substrate SUB2 and the semiconductor chip 100, and between the substrate SUB2 and the PMIC 300.

The semiconductor chip 200B may include a semiconductor device layer 210B in a portion adjacent to the surface S5″. The description of the semiconductor device layer 210B overlaps with the description of the semiconductor device layer 110, and thus, repeated description of the semiconductor device layer 210B will be omitted.

The surface S5″ of the semiconductor chip 200B may be the front surface of the semiconductor chip 200B, and the surface S6″ may be the back surface of the semiconductor chip. In this regard, the semiconductor chips 100 and 200B may be connected in a front-to-front configuration.

Connection terminals CT8 may be attached to the surface S5″ of the semiconductor chip 200B. The connecting terminals CT8 may include connecting terminals CT8A and connecting terminals CT8B. Lower portions of the connecting terminals CT8B may be connected to the semiconductor device layer 210B, and upper portions of the connecting terminals CT8B may be connected to the PMIC 300. Additionally, lower portions of the connecting terminals CT8B may be connected to the semiconductor device layer 210B, and upper portions of the connecting terminals CT8B may be connected to connection pads 130 of the semiconductor chip 100.

The semiconductor chip 200B may be connected to the semiconductor chip 100 through the connecting terminals CT8A and may thus exchange signals with the semiconductor chip 100. Additionally, the semiconductor chip 200B may be connected to the PMIC 300 through the connecting terminals CT8B and may thus receive the third power supply voltage generated by the PMIC 300.

The mold layer M may be disposed on the surface S2 of the substrate SUB2. The mold layer M may cover components mounted on the surface S2 of the substrate SUB2, such as the semiconductor chip 100, the PMIC 300, and connecting terminals CT2A, the connecting terminals CT8, and connecting terminals CT3A. The mold layer M may include an insulating polymer, such as an EMC.

In some example embodiments, the length of the PMIC 300 in the second direction X may be less than the length of the semiconductor chip 200 in the second direction X.

In some example embodiments, the ball pitch of connecting terminals CT4B may be defined as a length L1. Additionally, the distance from the edge of the PMIC 300 in the second direction X to the edge of the semiconductor chip 200 in the second direction X may be defined as a length L2. Additionally, the width of the semiconductor chip 200 in the second direction X may be defined as a length L3. Furthermore, the distance from the edge of the semiconductor chip 100 in the second direction X to the edge of the semiconductor chip 200 in the opposite direction of the second direction X may be defined as a length L4. In this case, the length L2 may be greater than or equal to the length L1. Additionally, the length of the PMIC 300 in the second direction X may be less than (L3−L4+L2).

In FIG. 13, the surface S6″ of the semiconductor chip 200B, which corresponds to the lower surface of the semiconductor chip 200B, and the surface S2 of the substrate SUB2, which corresponds to the upper surface of the substrate SUB2, are illustrated as being in contact and forming a coplanar surface, but example embodiments are not limited thereto. For example, when the surface S6″ of the semiconductor chip 200B and the surface S2 of the substrate SUB2 are spaced apart, the mold layer M may fill the space between the surfaces S6″ and S2.

In some example embodiments, the region where connecting terminals CT4 attached to the surface S1 of the substrate SUB2 are disposed may not overlap, in a plan view, with the region where the semiconductor chip 200B mounted within the substrate SUB2 is disposed. In this regard, because the semiconductor chips 100 and 200B in the semiconductor package 1000H are connected in a front-to-front configuration, there may not be a need to place connecting terminals in the region where the lower part of the substrate SUB2 overlaps, in a plan view, with the semiconductor chip 200B, to transmit signals or power to the semiconductor chip 200B. Accordingly, the number of balls required to manufacture the semiconductor package 1000H can be reduced.

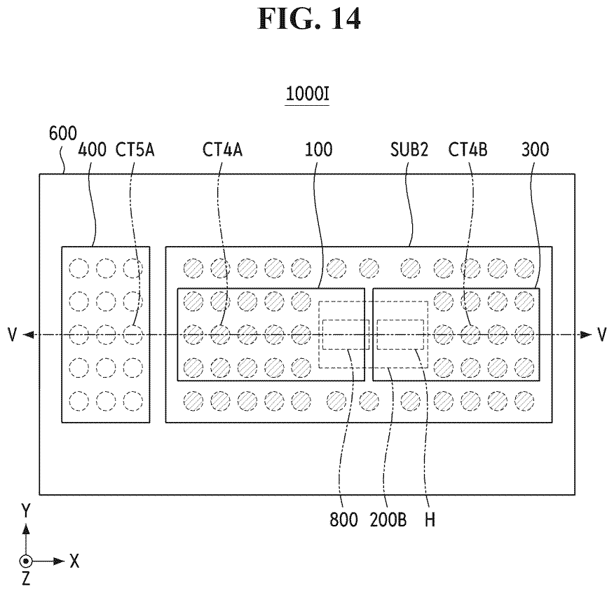

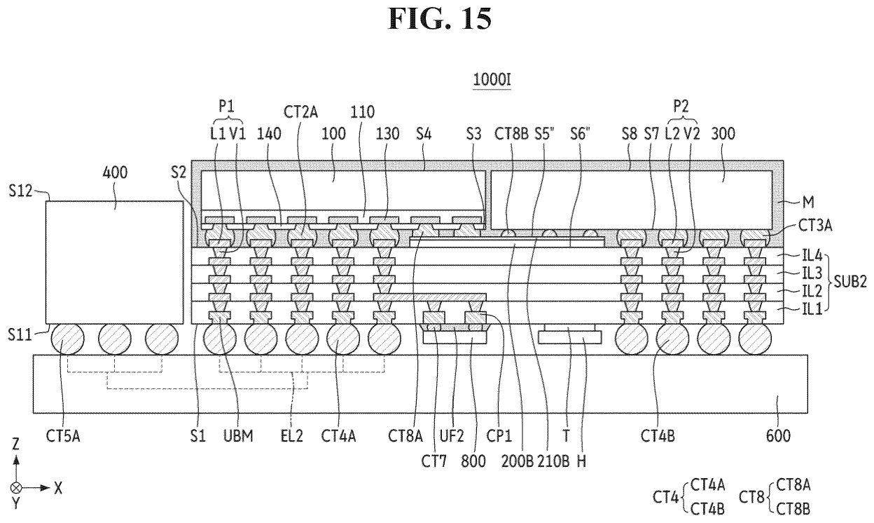

FIG. 14 is a plan view for explaining a semiconductor package according to some example embodiments. FIG. 15 is a cross-sectional view taken along line V-V of FIG. 14.

Referring to FIGS. 14 and 15, a passive element 800 and a heat path block (HPB) H may be attached to a surface S1 of a substrate SUB2. The passive element 800 and the HPB H may be disposed within the region of the surface S1 of the substrate SUB2 that overlaps, in a plan view, with the region where a semiconductor chip 200B mounted on a surface S2 of the substrate SUB2 is disposed. The description of the passive element 800 overlaps with the description of the passive element 800 of FIG. 11, and thus, repeated description of the passive element 800 will be omitted.

The HPB H may be disposed on the substrate SUB2. The HPB H may be disposed in areas of the surface S1 of the substrate SUB2 where the passive element 800 and connecting terminals CT4 are not disposed. The HPB H may include a thermal conductor to dissipate heat from the semiconductor package 1000I. The HPB H may be attached to the substrate SUB2 via a tape T. The HPB H may dissipate the heat generated by a semiconductor chip 100, a semiconductor chip 200, and a PMIC 300 to outside of a semiconductor package 1000I.

As the semiconductor chips 100 and 200B in the semiconductor package 1000I are connected in a front-to-front configuration, there may not be a need to place connecting terminals in the region of the lower part of the substrate SUB2 that overlaps, in a plan view, with the semiconductor chip 200B to transmit signals or power to the semiconductor chip 200B. Accordingly, the passive element 800 of the semiconductor chip 100 and/or the HPB H may be disposed within the region of the surface S1 of the substrate SUB2 that overlaps, in a plan view, with the region where the semiconductor chip 200B mounted on the surface S2 of the substrate SUB2 is disposed. This secures space for mounting passive elements for the high-power-consuming semiconductor chip 100 and allows for the heat generated by the semiconductor package 1000I to be effectively dissipated. Therefore, the utilization of the lower area of the substrate SUB2 can be increased.

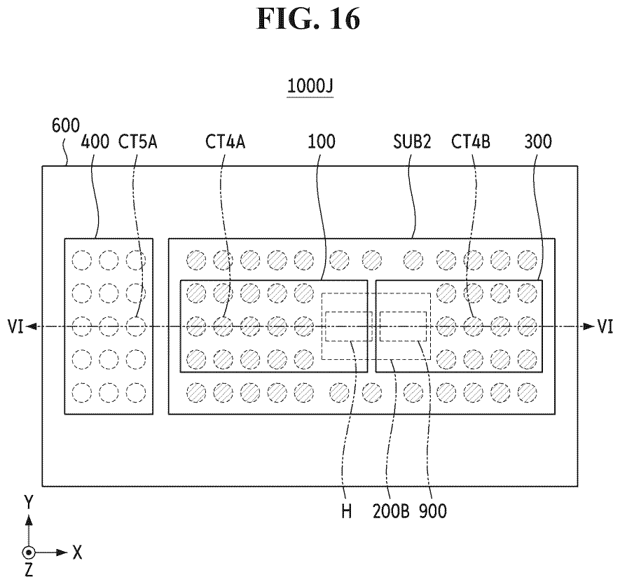

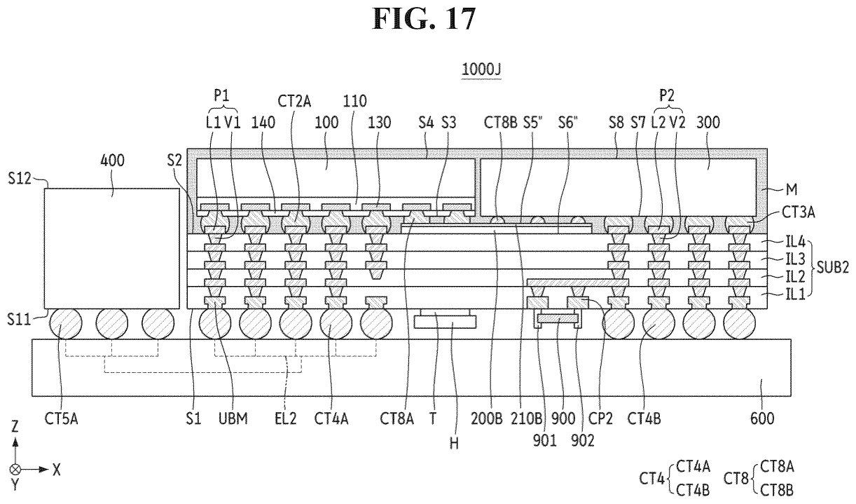

FIG. 16 is a plan view for explaining a semiconductor package according to some example embodiments. FIG. 17 is a cross-sectional view taken along line VI-VI of FIG. 16.

Referring to FIGS. 16 and 17, a passive element 900 and an HPB H may be attached to a surface S1 of a substrate SUB2. The passive element 900 and the HPB H may be disposed within the region of the surface S1 of the substrate SUB2 that overlaps, in a plan view, with the region where a semiconductor chip 200B mounted on a surface S2 of the substrate SUB2 is disposed. The description of the passive element 900 overlaps with the description of the passive element 900 of FIG. 11, and thus, repeated description of the passive element 900 will be omitted.

The HPB H may be disposed on the substrate SUB2. The HPB H may be disposed in areas of the surface S1 of the substrate SUB2 where the passive element 900 and connecting terminals CT4 are not disposed. The HPB H may dissipate the heat generated by a semiconductor chip 100, a semiconductor chip 200, and a PMIC 300 to outside of a semiconductor package 1000J.

As the semiconductor chips 100 and 200 in the semiconductor package 1000J are connected in a front-to-front configuration, there may not be a need to place connecting terminals in the region of the lower part of the substrate SUB2 that overlaps, in a plan view, with the semiconductor chip 200B to transmit signals or power to the semiconductor chip 200B. Accordingly, the passive element 900 of the PMIC 300 and/or the HPB H may be disposed within the region of the surface S1 of the substrate SUB2 that overlaps, in a plan view, with the region where the semiconductor chip 200B mounted on the surface S2 of the substrate SUB2 is disposed. This allows for securing space for mounting passive elements and effective dissipation of the heat generated by the semiconductor package 1000J. Therefore, the utilization of the lower area of the substrate SUB2 can be increased.

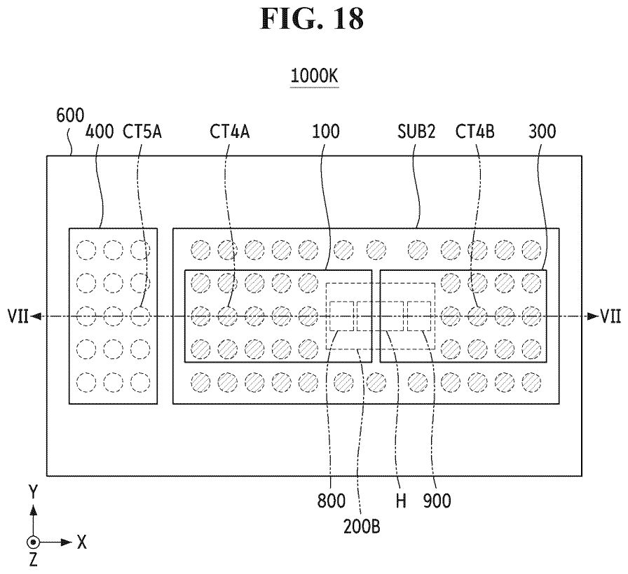

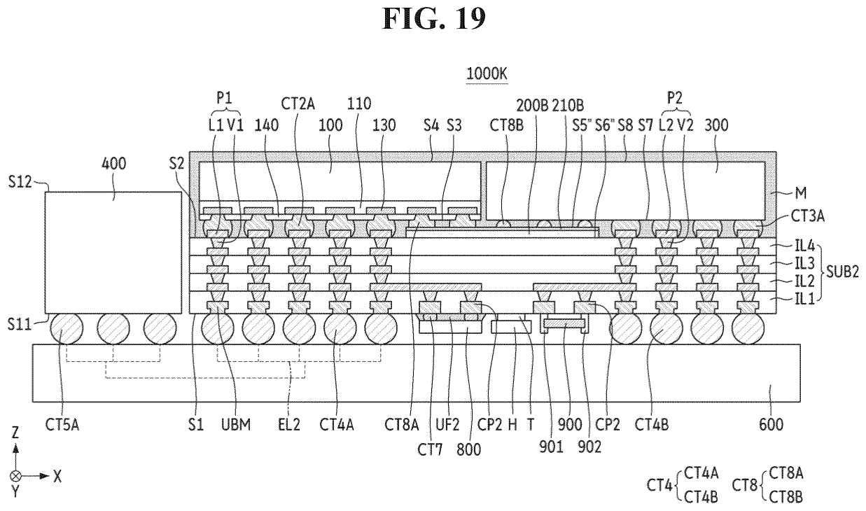

FIG. 18 is a plan view for explaining a semiconductor package according to some example embodiments. FIG. 19 is a cross-sectional view taken along line VII-VII of FIG. 18.

Referring to FIGS. 18 and 19, a passive element 800, a passive element 900, and an HPB H may be attached to a surface S1 of a substrate SUB2. The passive elements 800 and 900 and the HPB H may be disposed within the region of the surface S1 of the substrate SUB2 that overlaps, in a plan view, with the region where a semiconductor chip 200B mounted on a surface S2 of the substrate SUB2 is disposed. The descriptions of the passive elements 800 and 900 overlap with the descriptions of the passive elements 800 and 900 of FIG. 11, and thus, repeated description of the passive elements 800 and 900 will be omitted.

The HPB H may be disposed on the substrate SUB2. The HPB H may be disposed in areas of the surface S1 of the substrate SUB2 where the passive elements 800 and 900 and connecting terminals CT4 are not disposed. The HPB H may dissipate the heat generated by a semiconductor chip 100, a semiconductor chip 200, and a PMIC 300 to outside of a semiconductor package 1000K.

As the semiconductor chips 100 and 200B in the semiconductor package 1000K are connected in a front-to-front configuration, there may not be a need to place connecting terminals in the region of the lower part of the substrate SUB2 that overlaps, in a plan view, with the semiconductor chip 200B to transmit signals or power to the semiconductor chip 200B. Accordingly, the passive element 800 of the semiconductor chip 100, the passive element 900 of the PMIC 300, and the HPB H may be disposed within the region of the surface S1 of the substrate SUB2 that overlaps, in a plan view, with the region where the semiconductor chip 200B mounted on the surface S2 of the substrate SUB2 is disposed. This opens space to mount passive elements for the high-power-consuming semiconductor chip 100 and PMIC 300, and effectively dissipate the heat generated by the semiconductor package 1000K. Therefore, the utilization of the lower area of the substrate SUB2 can be increased.

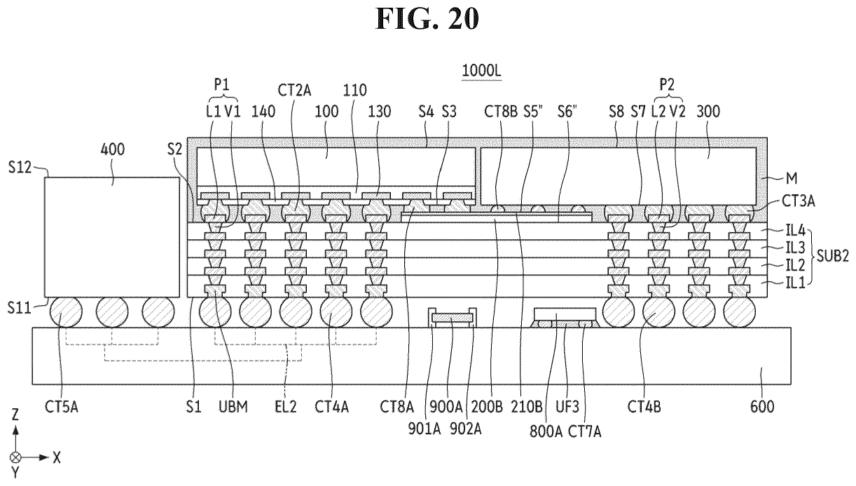

FIG. 20 is a diagram for explaining a semiconductor package according to some example embodiments.

Referring to FIG. 20, in a semiconductor package 1000L, passive elements 800A and 900A may be disposed on a surface S10 of a board 600. Connecting terminals CT7A of the passive element 800A and first and second conductive pads 901A and 902A of the passive element 900A may be electrically connected to wiring patterns within the board 600.

An underfill film UF3 may be disposed between the passive element 800A and the board 600, and spaced apart from the passive element 900A and connecting terminals CT4. The underfill film UF3 may electrically insulate the passive element 800A from the passive element 900A and the connecting terminals CT4. The underfill film UF3 may cover the entire connection surface of the passive element 800A, a portion of the surface S10 of the board 600, and the connecting terminals CT7A. The underfill film UF3 may include an insulating resin, such as an EMC.

The passive elements 800A and 900A may be passive elements, including a capacitor or an inductor. The passive elements 800A and 900A mounted on the surface S10 of the board 600 may be disposed within the region of the surface S10 that overlaps, in a plan view, with the region where a semiconductor chip 200B mounted on a surface S2 of the substrate SUB2 is disposed.

As described above, in the semiconductor package 1000L, as the semiconductor chips 100 and 200B are connected in a front-to-front configuration, there may not be a need to place connecting terminals in the region of the lower part of the substrate SUB2 that overlaps, in a plan view, with the semiconductor chip 200B to transmit signals or power to the semiconductor chip 200B.

Accordingly, in the space between the substrate SUB2 and the board 600 where the connecting terminals CT4 are not disposed, specifically within the region of the substrate SUB2 where the semiconductor chip 200B is mounted on the surface S2 of the substrate SUB2, there may be space to place the passive elements 800A and 900A. By placing the passive elements 800A and 900A for the board 600 in this space, the utilization of the lower area of the substrate SUB2 can be increased.

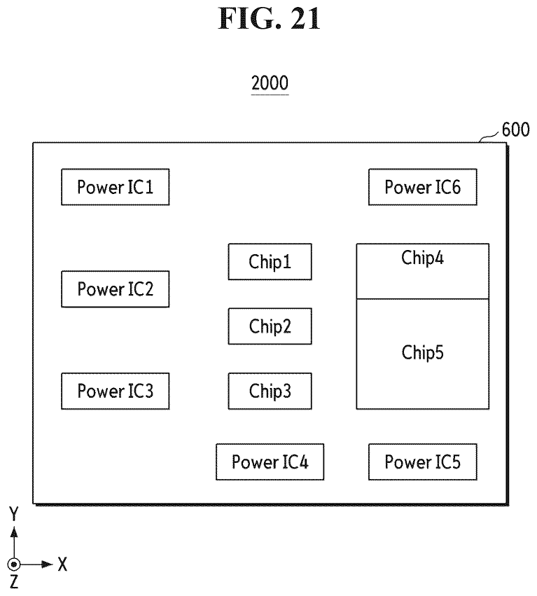

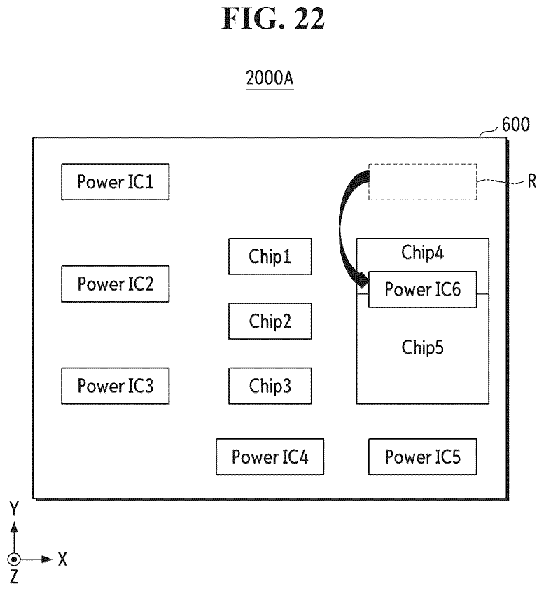

FIG. 21 is a diagram for explaining a semiconductor package. FIG. 22 is a diagram for explaining a semiconductor package according to some example embodiments.

FIGS. 21 and 22 schematically illustrate the configurations of semiconductor packages at the board level. Specifically, FIG. 21 is a schematic top view illustrating the configuration of a related semiconductor package 2000 at the board level, and FIG. 22 is a schematic top view illustrating the configuration of a semiconductor package 2000A according to example embodiments at the board level. The effects of some example embodiments will hereinafter be described with reference to FIGS. 21 and 22.

Referring first to FIG. 21, in the semiconductor package 2000, a plurality of semiconductor chips Chip1 through Chip5 and a plurality of sub power integrated chips (ICs) Power IC1 through Power IC6 may be mounted on a board 600. Each of the sub power ICs Power IC1 through Power IC6 may provide power supply voltages for operating the semiconductor chips Chip1 through Chip5. The sub power ICs Power IC1 through Power IC6 correspond to the PMICs of FIGS. 1 through 20. In the semiconductor package 2000, because the sub power ICs Power IC1 through Power IC6 that provide power supply voltages to the semiconductor chips Chip1 through Chip5 are mounted at the board level, it may be difficult to secure additional space at the board level. Additionally, because the distance between the semiconductor chips Chip1 through Chip5 and the respective sub power ICs Power IC1 through Power IC6 is relatively long, the performance of the PDN may degrade.

Referring to FIG. 22, in the semiconductor package 2000A, a sub power IC Power IC6 that provides a power supply voltage to semiconductor chips Chip4 and Chip5 may be vertically stacked (e.g., in the first direction Z) on the semiconductor chips Chip4 and Chip5. Accordingly, spatial room on the board 600 may be created in a region R. In some example embodiments, a battery may be additionally disposed in the secured region R to increase the battery capacity. Furthermore, the distances between the sub power IC Power IC6 and the semiconductor chips Chip4 and Chip5 for supplying the power supply voltage is reduced, thus improving the performance of the PDN.

While aspects of example embodiments have been particularly shown and described, it will be understood that various changes in form and details may be made therein without departing from the spirit and scope of the following claims.

What is claimed is:

1. A semiconductor package comprising:
a substrate comprising a first surface and a second surface that are opposite to each other in a first direction;
a first semiconductor chip on the second surface, and comprising a third surface facing the second surface and a fourth surface opposite to the third surface in the first direction;
a second semiconductor chip mounted within the substrate, wherein the second semiconductor chip is configured to operate based on a first power supply voltage, and comprises a fifth surface and a sixth surface that are opposite to each other in the first direction, the fifth surface faces the second surface and the sixth surface faces the first surface;
a first power management integrated circuit (PMIC) on the second surface, wherein the first PMIC is configured to generate the first power supply voltage, provide the first power supply voltage to the second semiconductor chip, and comprises a seventh surface facing the second surface and an eighth surface opposite to the seventh surface in the first direction;
first connecting terminals provided on the fifth surface;
second connecting terminals provided on the third surface; and
third connecting terminals provided on the seventh surface,
wherein a first plurality of the first connecting terminals are in contact with at least some of the second connecting terminals, and
wherein a second plurality of the first connecting terminals are in contact with at least some of the third connecting terminals.

2. The semiconductor package of claim 1, further comprising a board comprising a ninth surface and a tenth surface that are opposite to each other in the first direction,
wherein the tenth surface faces the first surface.

3. The semiconductor package of claim 2, further comprising:
a second PMIC configured to generate a second power supply voltage and provide the second power supply voltage to the first semiconductor chip; and
fourth connecting terminals between the second PMIC and the board,
wherein the first semiconductor chip is configured to operate based on the second power supply voltage.

4. The semiconductor package of claim 3, further comprising fifth connecting terminals between the substrate and the board,
wherein at least some of the fifth connecting terminals are connected to the fourth connecting terminals through first wiring patterns within the board.

5. The semiconductor package of claim 2, further comprising a second PMIC configured to generate the first power supply voltage and provide the first power supply voltage to the second semiconductor chip,
wherein the second PMIC is provided on the tenth surface of the board adjacent the substrate.

6. The semiconductor package of claim 5, further comprising:
fourth connecting terminals between the second PMIC and the board; and
fifth connecting terminals between the substrate and the board,
wherein at least some of the fifth connecting terminals are connected to the fourth connecting terminals through first wiring patterns within the board.

7. The semiconductor package of claim 1, further comprising fourth connecting terminals provided on the first surface,
wherein the fourth connecting terminals do not overlap the second semiconductor chip along the first direction.

8. The semiconductor package of claim 7, further comprising at least one passive element provided on the first surface,
wherein the at least one passive element overlaps the second semiconductor chip along the first direction.

9. A semiconductor package comprising:
a substrate comprising a first surface and a second surface that are opposite to each other in a first direction;
a first semiconductor chip disposed on the second surface, and comprising a third surface facing the second surface and a fourth surface opposite to the third surface in the first direction;
a second semiconductor chip disposed on the second surface, wherein the second semiconductor chip is configured to operate based on a power supply voltage, and comprises a fifth surface and a sixth surface that are opposite to each other in the first direction, the fifth surface faces the third surface and the sixth surface faces the second surface;
a power management integrated circuit (PMIC) on the second surface, wherein the PMIC is configured to generate the power supply voltage, provide the power supply voltage to the second semiconductor chip, and comprises a seventh surface facing the fifth surface and an eighth surface opposite to the seventh surface in the first direction; and
first connecting terminals provided on the fifth surface,
wherein a first plurality of the first connecting terminals are provided on the third surface, and
wherein a second plurality of the first connecting terminals are provided on the seventh surface.

10. The semiconductor package of claim 9, further comprising at least one passive element provided on the first surface,
wherein the at least one passive element overlaps the second semiconductor chip along the first direction.

11. The semiconductor package of claim 10, further comprising second connecting terminals between the first semiconductor chip and the substrate,
wherein the at least one passive element is connected to the first semiconductor chip through via portions and wiring portions within the substrate, and through the second connecting terminals.

12. The semiconductor package of claim 11, wherein a length of the first connecting terminals in the first direction is less than a length of the second connecting terminals in the first direction.

13. The semiconductor package of claim 10, further comprising second connecting terminals between the PMIC and the substrate,
wherein the at least one passive element is connected to the PMIC through via portions and wiring portions within the substrate, and through the second connecting terminals.

14. The semiconductor package of claim 9, further comprising a heat path block (HPB) provided on the first surface,
wherein the HPB overlaps the second semiconductor chip along the first direction.

15. A semiconductor package comprising:
a substrate comprising a first surface and a second surface that are opposite to each other in a first direction;
a first semiconductor chip on the second surface, and comprising a third surface facing the second surface and a fourth surface opposite to the third surface in the first direction;
a second semiconductor chip comprising a fifth surface and a sixth surface that are opposite to each other in the first direction, wherein the second semiconductor chip is configured to operate based on a power supply voltage; and
a power management integrated circuit (PMIC) on the second surface, wherein the PMIC is configured to generate the power supply voltage, provide the power supply voltage to the second semiconductor chip, and comprises a seventh surface facing the second surface and an eighth surface opposite to the seventh surface in the first direction,
wherein at least a first portion of the second semiconductor chip overlaps the first semiconductor chip along the first direction, and
wherein at least a second portion of the second semiconductor chip overlaps the PMIC along the first direction.

16. The semiconductor package of claim 15, further comprising:
a board comprising a ninth surface and a tenth surface that are opposite to each other in the first direction; and
at least one passive element on the tenth surface,
wherein the board is disposed on one side of the substrate such that the tenth surface faces the first surface, and
wherein the at least one passive element overlaps the second semiconductor chip along the first direction.

17. The semiconductor package of claim 15, wherein the second semiconductor chip is mounted within the substrate,
wherein the fifth surface faces the second surface,
wherein the sixth surface faces the first surface, and
wherein the semiconductor package further comprises third connecting terminals provided on the fifth surface.

18. The semiconductor package of claim 17, further comprising:
first connecting terminals provided on the third surface;
second connecting terminals provided on the seventh surface; and
a metal layer comprising a ninth surface and a tenth surface that are opposite to each other in the first direction,
wherein the first connecting terminals and the second connecting terminals contact the tenth surface, and
wherein the third connecting terminals contact the ninth surface.

19. The semiconductor package of claim 17, further comprising:
first connecting terminals provided on the third surface;
second connecting terminals provided on the seventh surface; and
via portions within the substrate,
wherein the via portions connect the first connecting terminals and the third connecting terminals, and
wherein the via portions connect the second connecting terminals and the third connecting terminals.

20. The semiconductor package of claim 15, further comprising a board comprising a ninth surface and a tenth surface that are opposite to each other in the first direction,
wherein the tenth surface faces the first surface,
wherein the fifth surface faces the first surface, and
wherein the sixth surface faces the tenth surface.
